(19) United States
(12) Patent Application Publication
(10) Pub. No.: US 2011/0259951 A1
(43) Pub. Date: Oct. 27, 2011

(54) Method for Tracing Individual Dies

(75) Inventors: Charles M. Meyerson, Scottsville, AZ (US); Eric J. Dickes, Scottsdale, AZ (US); William V. Gorton, Chandler, AZ (US); Stephen W. Graham, Colorado Springs, CO (US); Kenneth Heames, Mesa, AZ (US); Dennis B. Johnson, Candler, AZ (US); Christopher D. Ohme, Gilbert, AZ (US); Steven C. Warren, Phoenix, AZ (US)

(73) Assignee: MEDTRONIC, INC., Minneapolis, MN (US)

(21) Appl. No.: 12/767,231

(22) Filed: Apr. 26, 2010

(51) Int. Cl. G06F 17/00; H01L 21/50; G06K 19/06; H01L 21/78

(52) U.S. Cl. 235/375; 438/113; 438/109; 235/494; 257/E21.599; 257/E21.499

(57) ABSTRACT

A method for tracing individual dies within stacked chip scale packages includes the steps of recording unique die identifiers from layers of marked dies and associating the unique identifiers with a die bonding substrate and the resulting die or stacked chip scale packages. The unique die identifiers are also associated with wafer numbers, x-y positions on a wafer, wafer lot numbers or any combination thereof.

### BACKGROUND

The invention relates generally to die marking and die traceability of dies in chip scale packages (CSPs) and stacked chip scale packages (SCSPs).

Many manufacturers are using stacked chip scale packages (SCSPs) that contain multiple thinned die stacked on top of one another. Such a configuration is desirable because it saves space on a circuit board. Saving space on a circuit board becomes more important as components and the devices that use such components become smaller in area and volume. Single dies and SCSPs are also used in system in packages (SIPs)

Typically these SCSPs and SIPs are encapsulated for protection and heat dissipation. Although the encapsulant protects the dies or stack of dies, the individual dies are not visible or easily identifiable. However, in the event of a quality or reliability issue associated with the SCSP or SIP within a device, it would be desirable to be able to trace the origin of the die stack to an individual wafer.

### SUMMARY

In one embodiment, the invention provides a method for tracing individual dies. In this embodiment, the method comprises providing a wafer having a plurality of dies, the wafer being associated with a wafer lot number, and a wafer number; marking a major surface of each die with a unique die identifier which comprises the wafer lot number, the wafer number and an x-y location of each die on the wafer to form marked dies; separating the plurality of marked dies from the wafer; bonding marked dies to a substrate having a unique substrate identifier to form at least a first layer of marked dies, each of the marked dies of the at least first layer having a first layer x-y position on the substrate; recording each of the unique die identifiers and the first layer x-y positions of the at least first layer of marked dies on the substrate, and recording the unique substrate identifier; associating the unique die identifiers with the first layer x-y positions of each of the at least first layer marked dies on the substrate and with the unique substrate identifier; encapsulating the at least first layer of marked dies with an encapsulant to form encapsulated dies; marking each encapsulated die with a unique encapsulated die identifier, each encapsulated die having an encapsulated die x-y position on the substrate; recording each of the encapsulated die identifiers and each of the encapsulated die x-y positions; and associating each encapsulated die identifier with each of the unique die identifiers of each of the dies and the unique substrate identifier. The encapsulated dies can be diced to form chip scale packages.

In another embodiment, the invention provides a method for tracing individual dies within a stacked die package. In this embodiment, the method comprises bonding marked dies to a substrate having a unique substrate identifier to form a first layer of marked dies, each of the marked dies of the first layer having a first layer x-y position on the substrate; recording each of the unique die identifiers and the first layer x-y positions of the first layer of marked dies on the substrate, and recording the unique substrate identifier; associating the unique die identifiers with the first layer x-y positions of each of the first layer marked dies on the substrate and with the unique substrate identifier; bonding a second layer of marked dies to the first layer of marked dies to form die stacks, each of the marked dies of the second layer of marked dies having a second layer x-y position on the substrate; recording each of the unique die identifiers and the second layer x-y positions of the second layer marked dies on the substrate, and recording the unique substrate identifier; associating the unique die identifiers with the second layer x-y positions of the second layer marked dies on the substrate and with the unique substrate identifier; encapsulating the die stacks with an encapsulant to form encapsulated die stacks; marking each encapsulated die stack with a unique die stack identifier, each encapsulated die stack having a die stack x-y position on the substrate; recording each of the die stack identifiers and each of the die stack x-y positions; and associating each die stack identifier with each of the unique die identifiers of each of the dies in the die stack and the unique substrate identifier. The dies stacks can be diced to form individual die stacks that can be individually packaged and mounted on or in a device.

In another embodiment, a method for tracing individual dies within a stacked die package further comprises providing a wafer having a plurality of dies, the wafer being associated with a wafer lot number, and a wafer number; marking a major surface of each die with a unique die identifier which comprises the wafer lot number, the wafer number and an x-y location of each die on the wafer to form marked dies; and separating the plurality of marked dies from the wafer.

### BRIEF DESCRIPTION OF THE DRAWINGS

FIG. 1 is a plan view of a wafer having marked dies on a major surface;

FIG. 2 is a plan view of a substrate having a first layer of marked dies mounted onto the substrate;

FIG. 3 is a plan view of a substrate having a second layer of marked dies mounted onto the substrate; and

FIG. 4 is a plan view of encapsulated die stacks on a substrate.

### DETAILED DESCRIPTION

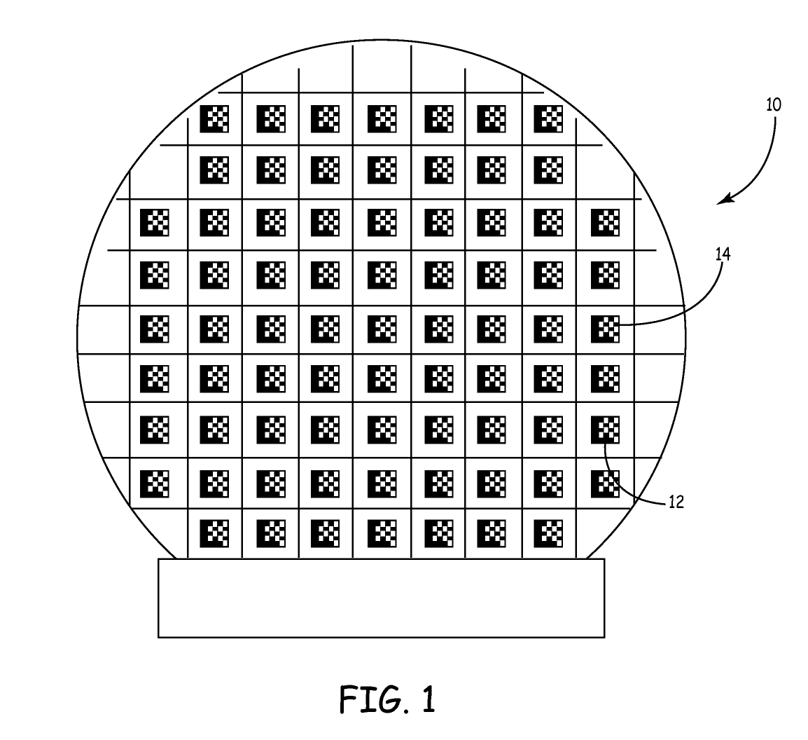

FIG. 1 depicts a wafer 10 having a plurality of die 12 formed on a wafer surface. Typically, the wafer has been thinned in order to produce thin die. In this embodiment, each of the die is uniquely marked with a data matrix 14. The data matrix 14 contains readable information about the die. For example, the data matrix on each of the die can contain the wafer lot number, the wafer number, the x-y location of the die on the wafer, and combinations of any or all of the listed information. The wafer number and/or wafer lot number can be associated with information such as date of manufacture, location of manufacture, identification of equipment used during manufacture, source of raw material, raw material analysis results, and combinations of any of them. Of course, the marking on the die could be of any other type including barcode, and alpha-numeric symbols, or a combination of any of them. The markings may be made using marking methods such as digital lithography, printing using opaque or fluorescent inks, using a photoresist, dot-peen, and LASERs or a combination of any of them.

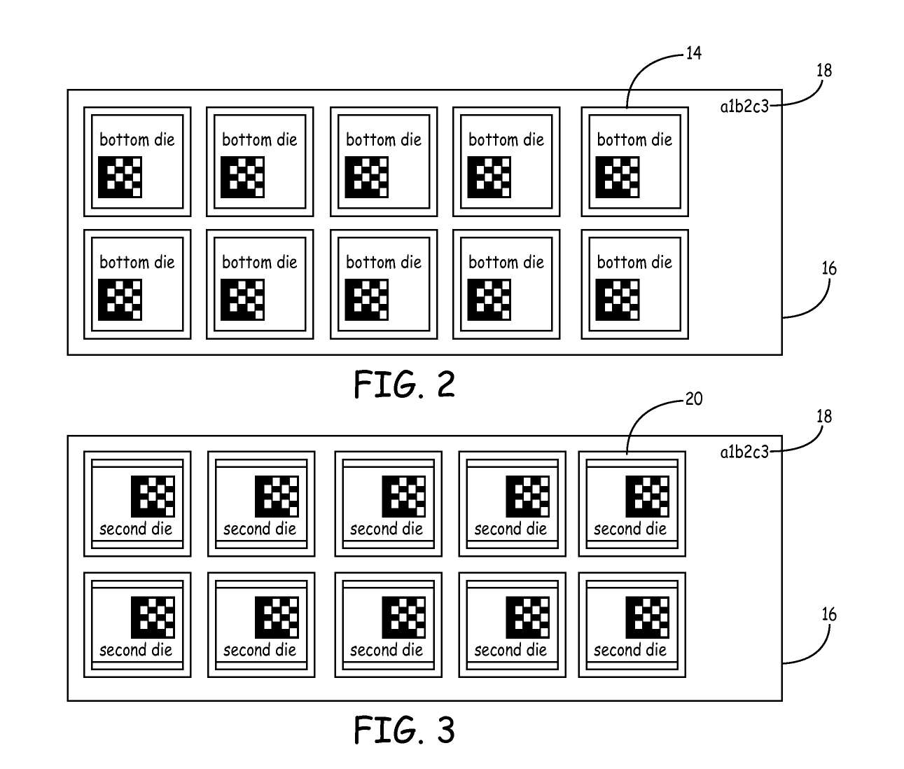

After the individual dies are marked with the desired marking, the wafer is diced to form individual dies. Referring to FIG. 2, a first layer of individual marked dies 14 are bonded to a substrate 16 having a unique substrate identifier 18. The x-y position of each marked die of the first die layer on the substrate, the data matrix 14, and the substrate identifier are read and recorded. The x-y positions of the first layer of marked dies, each data matrix 14 and the substrate identifier 18 are associated with one another. Other data that can be associated with the substrate identifier include the date of bonding of the die, lot number and/or type of die bond used, die bonding machine or line, wire bonder used, encapsulation machine used, lot number of encapsulant used and combinations thereof. In one embodiment, the single layer of marked dies are encapsulated to form encapsulated dies. The encapsulated dies are then marked with a unique encapsulated die identifier, the unique encapsulated die identifier can be associated with an x-y position on the substrate and the unique substrate identifier. The encapsulated dies can be diced to form individual chip scale packages.

The x-y position of the marked dies, the marking on each of the dies, and the substrate identifier can be read using scanning techniques such as those which utilize charge-coupled devices (CCDs) and active pixel sensors (APS). Once the data is read, the data may be recorded and associated using commercially available software programs such as a spreadsheet database such as MICROSOFT EXCEL or an SQL database.

As shown in FIG. 3, a second layer of marked dies 20 is bonded to the first layer of marked dies to form die stacks consisting of two dies. As with the first layer of marked dies 14, the x-y positions on the substrate and data matrix relating to the second layer of marked dies 20 as well as the substrate identifier are read, recorded, and associated. Additional layers of marked dies can also be bonded to the second layer of dies to form stacks containing 3 or more dies, 4 or more dies, or 5 or more dies, in each stack.

Additionally, each layer could also comprise multiple, smaller die. For example, the second layer of a die stack could be two or four smaller die, for example, die having 50% or 25% of the area of the die below, on top of a larger first layer die or on each of the die of the first layer of marked dies. Dummy spacers or die can also be placed in between or on top of die that is/are functional.

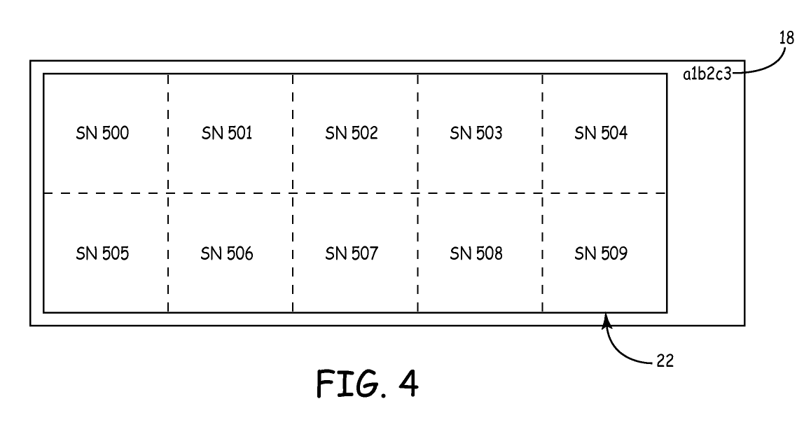

Once the desired number of marked dies are bonded into a die stack on the substrate, the die stacks are encapsulated with an encapsulant 22 as shown in FIG. 4. After the die stacks are encapsulated, each encapsulated die stack 24 is marked with a unique die stack identifier 26, for example, a die stack serial number. (Show in FIG. 4) Methods of marking include those described above. The die stack identifier and the substrate identifier are read, stored, and associated. The x-y position of each die stack on the substrate may also be recorded and associated with the die stack identifier and the substrate identifier.

The die stacks, along with the associated information file containing the unique data matrix for each die, the substrate identifier, the x-y location of each die on the substrate and the die stack identifier, can then be shipped or transferred to a device manufacturer for combination with other components. The die stack identifier of each of the die stacks can then be associated with a serial number or other identifier of the device for example, by scanning. In this way, each of the dies in the die stack can be traced back to the substrate on which there were stacked, the wafer lot number in which they were manufactured, the individual wafer number from which they came, and the x-y position on that wafer from which they were picked up and placed on the substrate. In the case of a quality or reliability issue all of the dies from an individual wafer can be easily traced to specific die stacks and the devices that contain them. The owners or recipients of the devices can then be easily identified and notified in the case of a product recall or a functional or quality issue with an individual die or dies from a wafer.

Table 1 below shows the association of simplified identification data of the die the substrate, and the resulting SCSP. In this example, it is assumed that the die marking has been associated with the wafer number, wafer lot number, and x-y position of the die on the wafer.

TABLE 1

| | Substrate | Substrate | Substrate |
|---|---|---|---|
| Substrate ID: a1b2c3 | Position 1 | Position 2 | Position 3 |
| Layer 1 (Die ID) | d4e5f6 | g7h8i9 | j0k1l2 |
| Layer 2 (Die ID) | m3n4o5 | p6q7r8 | s9t0u1 |
| Layer 3 (Die ID) | v2w3x4 | y5z6a7 | b8c9d0 |
| SCSP Serial No. | 500 | 501 | 502 |
| Associated Data: | | | |
| Substrate ID: | a1b2c3 | a1b2c3 | a1b2c3 |
| First Die: | d4e5f6 | g7h8i9 | j0k1l2 |
| Second Die | m3n4o5 | p6q7r8 | s9t0u1 |
| Third Die | v2w3x4 | y5z6a7 | b8c9d0 |
| SCSP SN: | 500 | 501 | 502 |

The methods disclosed herein can be used to trace individual dies within an SCSP that is used within virtually any device. The tracing can be done from the device or recipient of the device to the individual die or vice versa. Examples of such devices include implantable medical devices, for example, pacemakers, defibrillators, stimulators, or data recorders and combinations thereof; computers; servers; circuit boards; cellular phones, and other portable electronic devices. In the case of medical devices, the identifying information of the medical device can be associated with a recipient, for example, a distributor, a hospital, a clinic, a patient, a physician, or a combination of any of them. In other devices, the identifying information of the device can be associated with a consumer or user of the device.

The methods herein can also be used to trace individual dies within a “system in package” (SIP). An SIP is a fully functional system or subsystem in an integrated circuit package format which is typically encapsulated. In addition to stacked chips (unencapsulated) or an SCSP, an SIP may also have other components mounted on an SIP substrate. Examples of such components include passive components, for example, integrated passive networks, substrate-imbedded passives and surface-mounted discreet passive components. Other components mounted on an SIP substrate include filters, EMI shields, connectors, and other mechanical parts.

In a method where a marked encapsulated die stack is mounted on an SIP substrate, and the SIP substrate is encapsulated, the encapsulated SIP is marked with a unique identifier which can be associated with the “die stack identifier” using the techniques discussed above.

In a method where an un-encapsulated die stack or a single die is mounted on an SIP substrate, and the SIP substrate is encapsulated, the encapsulated SIP is marked with a unique identifier which can be associated with the individual unique die identifiers on each die of the stack. The techniques for marking encapsulated die stacks and associating unique die stack identifiers can be used for marking and associating encapsulated SIPs with individual dies, wafers, wafer lot numbers, manufacturing facility, manufacturing equipment, the date of bonding of the die, lot number and/or type of die bond used, die bonding machine or line, wire bonder used, encapsulation machine used, lot number of encapsulant used and combinations thereof.

Various examples have been described. These and other examples are within the scope of the invention defined by the following claims.

What is claimed is:

1. A method for tracing individual dies comprising:
providing a wafer having a plurality of dies, the wafer being associated with a wafer lot number, and a wafer number;
marking a major surface of each die with a unique die identifier which comprises the wafer lot number, the wafer number and an x-y location of each die on the wafer to form marked dies;
separating the plurality of marked dies from the wafer;
bonding marked dies to a substrate having a unique substrate identifier to form at least a first layer of marked dies, each of the marked dies of the at least first layer having a first layer x-y position on the substrate;
recording each of the unique die identifiers and the first layer x-y positions of the at least first layer of marked dies on the substrate, and recording the unique substrate identifier;
associating the unique die identifiers with the first layer x-y positions of each of the at least first layer marked dies on the substrate and with the unique substrate identifier;
encapsulating the at least first layer of marked dies with an encapsulant to form encapsulated dies;
marking each encapsulated die with a unique encapsulated die identifier, each encapsulated die having an encapsulated die x-y position on the substrate;
recording each of the encapsulated die identifiers and each of the encapsulated die x-y positions; and
associating each encapsulated die identifier with each of the unique die identifiers of each of the dies and the unique substrate identifier.

2. The method of claim 1 further comprising:
bonding a second layer of marked dies to the at least first layer of marked dies to form die stacks, each of the marked dies of the second layer of marked dies having a second layer x-y position on the substrate;
recording each of the unique die identifiers and the second layer x-y positions of the second layer marked dies on the substrate, and recording the unique substrate identifier; and
associating the unique die identifiers with the second layer x-y positions of the second layer marked dies on the substrate and with the unique substrate identifier.

3. The method of claim 1 further comprising the step of associating the encapsulated die identifier with an identifier of a device containing the die stack.

4. The method of claim 3 wherein the device is an implantable medical device.

5. The method of claim 1 wherein the die identifier comprises a data matrix, a barcode, alpha-numeric symbols, or a combination thereof.

6. The method of claim 1 wherein the die are marked using digital lithography, opaque inks, fluorescent inks, photoresist, dot-peen, LASER, or a combination thereof.

7. The method of claim 2 further comprising the step of bonding a third layer of marked dies to the second layer of marked dies to form die stacks, each of the marked dies of the third layer of marked dies having a third layer x-y position on the substrate.

8. The method of claim 7 wherein the third layer of marked dies comprises multiple die bonded to a second layer die.

9. The method of claim 4 wherein the implantable medical device is selected from pacemakers, defibrillators, stimulators, data recorders or combinations thereof.

10. The method of claim 4 further comprising the step of locating the implantable medical device.

11. The method of claim 4 further comprising the step of associating the identifier of the implantable medical device with a recipient of the implantable medical device.

12. The method of claim 11 further comprising the step of notifying the recipient.

13. The method of claim 1 further comprising the step of locating all devices containing encapsulated dies associated with a single wafer.

14. The method of claim 1 further comprising dicing the encapsulated dies to form chip scale packages.
